(19) United States
(12) Patent Application Publication
(10) Pub. No.: US 2024/0402657 A1
(43) Pub. Date: Dec. 5, 2024

(54) WEARABLE ELECTRONIC DEVICE

(71) Applicant: Samsung Electronics Co., Ltd., Suwon-si (KR)

(72) Inventor: Junghyun KANG, Suwon-si (KR)

(21) Appl. No.: 18/678,402

(22) Filed: May 30, 2024

Related U.S. Application Data
(63) Continuation of application No. PCT/KR2024/007001, filed on May 23, 2024.

(30) Foreign Application Priority Data
May 31, 2023 (KR) 10-2023-0069828
Aug. 25, 2023 (KR) 10-2023-0112289

(51) Int. Cl. G04G 21/02; G06F 1/16; G06V 40/13

(52) U.S. Cl. CPC G04G 21/025; G06F 1/163; G06F 1/1656; G06V 40/13

(57) ABSTRACT

An electronic device according to an embodiment of the disclosure may include: a housing including an opening formed through a first surface of the housing, and a fingerprint sensor assembly coupled so that at least a part of the fingerprint sensor assembly is disposed to pass through the opening, wherein the fingerprint sensor assembly includes: a fingerprint sensor, a conductive waterproof film attached to one surface of the fingerprint sensor, and a first printed circuit board at least partially attached to one surface of the conductive waterproof film, the opening includes a first space exposed to the outside of the electronic device and having a first size, and a second space extending from the first space in an inner direction of the electronic device and having a second size smaller than the first size, and the fingerprint sensor assembly is positioned within the first space.

### CROSS-REFERENCE TO RELATED APPLICATIONS

This application is a continuation of International Application No. PCT/KR2024/007001 designating the United States, filed on May 23, 2024, in the Korean Intellectual Property Receiving Office and claiming priority to Korean Patent Application Nos. 10-2023-0069828, filed on May 31, 2023 and 10-2023-0112289, filed on Aug. 25, 2023, in the Korean Intellectual Property Office, the disclosures of each of which are incorporated by reference herein in their entireties.

### BACKGROUND

### Field

The disclosure relates to a wearable electronic device.

### Description of Related Art

Thanks to remarkable developments in information communication technology and semiconductor technology, the distribution and use of various electronic devices is rapidly increasing. In particular, recent electronic devices are being developed to perform communication while being carried.

The term “electronic device” may refer to a device which performs a specific function according to its equipped program, such as a home appliance, an electronic scheduler, a portable multimedia player, a mobile communication terminal, a tablet PC, a video/sound device, a desktop/laptop computer, and a navigation device for automobile. For example, these electronic devices may output stored information as sound or video. As electronic devices are highly integrated and high-speed and high-volume wireless communication becomes commonplace, an electronic device, such as a mobile communication terminal, is recently being equipped with various functions. For example, in addition to a communication function, an entertainment function such as games, a multimedia function such as music/video playback, a communication and security function such as mobile banking, and a function such as schedule management or an electronic wallet are integrated into one electronic device. Such electronic devices are being miniaturized so that users can conveniently carry the devices.

### SUMMARY

An electronic device according to an example embodiment of the disclosure may include: a housing including an opening formed through a first surface of the housing, and a fingerprint sensor assembly coupled so that at least a part of the fingerprint sensor assembly extends through the opening, wherein the fingerprint sensor assembly includes a fingerprint sensor, a conductive waterproof film attached to one surface of the fingerprint sensor, and a first printed circuit board at least partially attached to one surface of the conductive waterproof film, wherein the opening includes a first space exposed to the outside of the electronic device and having a first size, and a second space extending from the first space in an inner direction of the electronic device and having a second size smaller than the first size, wherein the fingerprint sensor assembly is positioned within the first space.

An electronic device according to an example embodiment of the disclosure may include: a housing including an opening formed through a first surface of the housing, and a fingerprint sensor assembly coupled so that at least a part of the fingerprint sensor assembly extends through the opening, wherein the fingerprint sensor assembly includes a fingerprint sensor, a conductive waterproof film attached to one surface of the fingerprint sensor, a first printed circuit board including a first area at least partially attached to the conductive waterproof film and a second area bent in a vertical direction from the first area, a reinforcement plate at least partially attached to the conductive waterproof film, an adhesive member comprising an adhesive disposed on the first area of the first printed circuit board and the reinforcement plate and including a first hole provided at a position corresponding to the second area of the first printed circuit board, a support disposed on the adhesive member and including a second hole provided at a position corresponding to the second area of the first printed circuit board, and an epoxy disposed to fill the first hole of the adhesive member and the second hole of the support, the opening including a first space exposed to the outside of the electronic device and having a first size, and a second space extending from the first space in an inner direction of the electronic device and having a second size smaller than the first size, wherein the fingerprint sensor assembly is positioned within the first space.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a front perspective view of a wearable electronic device according to various embodiments;

FIG. 3 is a rear perspective view of a wearable electronic device according to various embodiments;

FIG. 4 is an exploded perspective view of a wearable electronic device according to various embodiments;

FIG. 5 is a diagram illustrating a side view of a housing including a fingerprint sensor assembly according to various embodiments;

FIG. 6 is a partial perspective view showing a part of a housing including a fingerprint sensor assembly according to various embodiments;

FIG. 7 is a partial perspective view showing a fingerprint sensor assembly and a housing which are being coupled to each other according to various embodiments;

FIG. 8 is a perspective view illustrating a fingerprint sensor assembly according to various embodiments;

FIG. 9 is an exploded perspective view showing an example configuration of a fingerprint sensor assembly in a separated state according to various embodiments;

FIG. 10 is an exploded perspective view showing the fingerprint sensor assembly of FIG. 9 in a separated state according to various embodiments;

FIG. 11 is an exploded perspective view showing the configuration of a fingerprint sensor assembly in a separated state according to various embodiments;

FIGS. 12A, 12B and 12C include various diagrams and views illustrating an example fingerprint sensor according to various embodiments;

FIG. 13 is a diagram illustrating a second surface of a fingerprint sensor according to various embodiments;

FIGS. 14 and 15 are diagrams illustrating an example electrical connection process of a fingerprint sensor, a conductive waterproof film, and a first printed circuit board according to various embodiments;

FIG. 16 is a partial exploded perspective view illustrating a fingerprint sensor assembly being coupled to a housing according to various embodiments;

FIG. 17 is a cross-sectional view of a portion of a housing coupled with a fingerprint sensor assembly according to various embodiments;

FIG. 18 is a diagram illustrating a side view of a housing including a fingerprint sensor assembly according to various embodiments; and

FIG. 19 is a cross-sectional view of a portion of a housing coupled with a fingerprint sensor assembly according to various embodiments.

### DETAILED DESCRIPTION

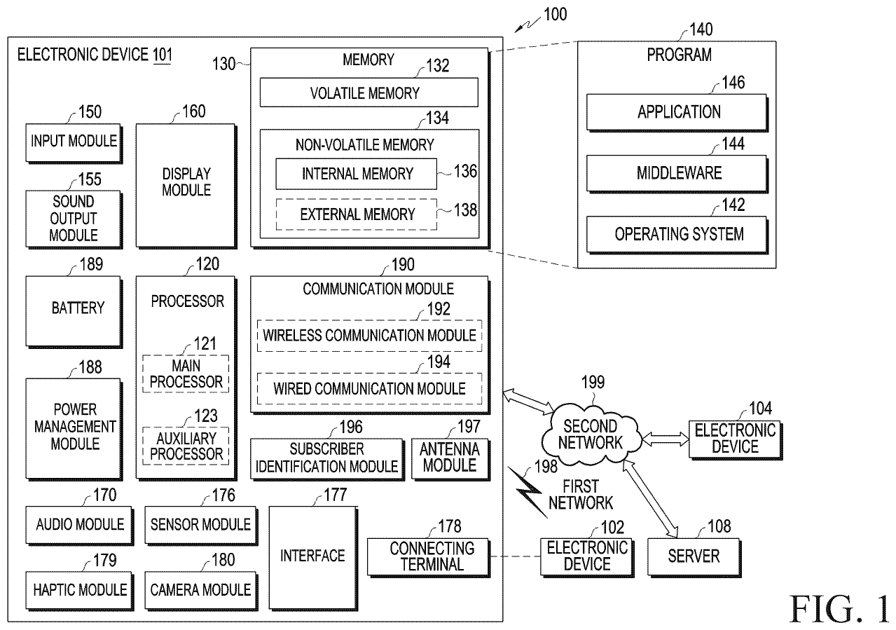

FIG. 1 is a block diagram illustrating an example electronic device in a network environment according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (cMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

In the detailed description below, a longitudinal direction, a transverse direction, and/or a thickness direction of an electronic device may be mentioned, and the longitudinal direction may refer, for example, to a “Y-axis direction”, the transverse direction may refer, for example, to an “X-axis direction”, and/or the thickness direction may refer, for example, to a “Z-axis direction”. In an embodiment, in relation to a direction in which a component is directed, “negative and positive (−/+)” may be mentioned together in addition to an orthogonal coordinate system illustrated in the drawings. For example, a front surface of the electronic device or a housing may refer, for example, to a “surface facing the +Z direction”, and a rear surface thereof may refer, for example, to a “surface facing the −Z direction”. In an embodiment, a lateral surface of the electronic device or the housing may include an area facing the +X direction, an area facing the +Y direction, an area facing the −X direction, and/or an area facing the −Y direction. Further, in an embodiment, the “X-axis direction” may refer, for example, to including both the “−X direction” and “+X direction”. It is noted that this is based on the orthogonal coordinate system illustrated in the drawings for briefness of description, and that the description of directions or components does not limit the disclosure.

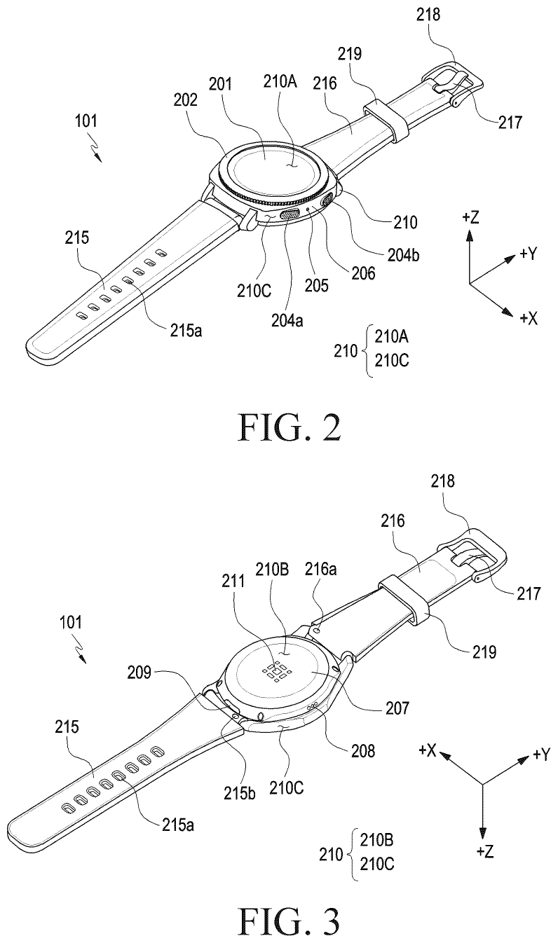

FIG. 2 is a front perspective view showing a wearable electronic device according to various embodiments. FIG. 3 is a rear perspective view showing the wearable electronic device of FIG. 2 according to various embodiments.

The configuration of a wearable electronic device 101 of FIGS. 2 and 3 may be wholly or partly the same as the configuration of the electronic device (or wearable electronic device) 101 of FIG. 1.

In the detailed description below, in FIGS. 2 and 3, a transverse direction or a longitudinal direction of the wearable electronic device 101 or a housing 210 may be one direction among the “X-axis direction” and the “Y-axis direction” of the illustrated orthogonal coordinate system. When distinction between the transverse direction and longitudinal direction is necessary, the direction of the orthogonal coordinate system illustrated in the drawings may be written together. In the orthogonal coordinate system of FIGS. 2 to 4, the “Z-axis direction” may refer, for example, to a thickness direction of the wearable electronic device 101 or the housing 210. In an embodiment, a direction in which a front surface (e.g., a first surface 210A of FIG. 2) of the wearable electronic device 101 or the housing 210 faces may refer, for example, to a “first direction” or the “+Z direction”, and a direction in which a rear surface (e.g., a second surface 210B of FIG. 3) of the wearable electronic device 101 or the housing 210 faces may refer, for example, to a “second direction” or the “−Z direction”.

Referring to FIGS. 2 and 3, the wearable electronic device 101 according to an embodiment may include the housing 210 including a first surface (or a front surface) 210A, a second surface (or a rear surface) 210B, and a lateral surface 210C surrounding a space between the first surface 210A and the second surface 210B, and wearing members 215 and 216 (e.g., bands) connected to at least a part of the housing 210 and configured to wear the wearable electronic device 101 or the housing 210 on a part of a user's body (e.g., a wrist or an ankle). In an embodiment (not shown), the housing 210 may refer to a structure which forms a part of the first surface 210A, the second surface 210B, and the lateral surface 210C of FIG. 2. According to an embodiment, the first surface 210A may be configured by a front plate 201 (e.g., a glass plate or a polymer plate including various coating layers), at least a part of which is substantially transparent. The second surface 210B may be configured by a rear plate 207 which is substantially opaque. In an embodiment, when the electronic device includes a first sensor module 211 disposed on the second surface 210B, the rear plate 207 may include an area which is at least partially transparent. The rear plate 207 may be formed of, for example, coated or colored glass, ceramic, a polymer, or a metal (e.g., aluminum, stainless steel (STS), or magnesium), or a combination of two or more of the above materials. The lateral surface 210C may be configured by a lateral bezel structure (or a “lateral member”) 206 coupled to the front plate 201 and/or the rear plate 207 and including a metal and/or a polymer. In an embodiment, the rear plate 207 and the lateral bezel structure 206 may be integrally configured and may include the same material (e.g., a metal material such as aluminum). The wearing members 215 and 216 may be configured to have various materials and shapes. An integrated unit link and a plurality of unit links may be formed to be movable with respect to each other using a woven fabric, leather, rubber, urethane, metal, ceramic, or a combination of at least two of the above materials.

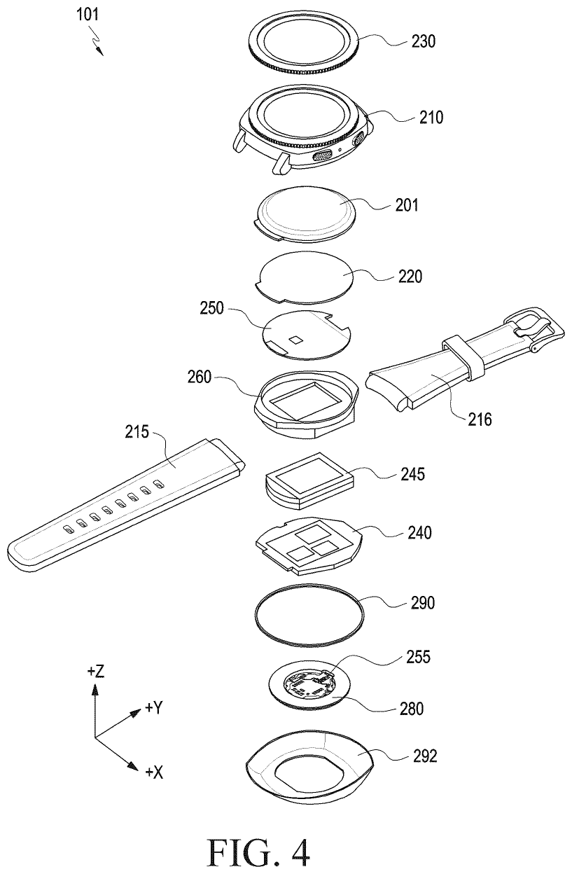

According to an embodiment, the wearable electronic device 101 may include at least one of a display 220 (referring to FIG. 4) (e.g., the display device 160 of FIG. 1), audio modules 205 and 208, the first sensor module 211 (e.g., the sensor module 176 of FIG. 1), and key input device 202, 204a, and 204b, and a connector hole 209. In an embodiment, the wearable electronic device 101 may not include at least one (e.g., the key input devices 202, 204a, and 204b, the connector hole 209, or the first sensor module 211) of the components or may additionally include another component.

For example, a display (e.g., the display 220 of FIG. 4) may be visible through a significant part of the front plate 201. The shape of the display 220 may be a shape corresponding to the shape of the front plate 201, and may have various shapes such as a circle, an oval, or a polygon. The display 220 may be coupled to or disposed adjacent to a touch detection circuit, a pressure sensor capable of measuring the intensity (pressure) of a touch, and/or a fingerprint sensor.

Audio holes 205 and 208 may include a microphone hole 205 and a speaker hole 208. The microphone hole 205 may include a microphone disposed therein so as to acquire external sound, and in an embodiment, multiple microphones may be disposed in the microphone hole so as to detect the direction of sound. The speaker hole 208 may be used as an external speaker and a receiver for calls. According to an embodiment, a speaker may be included without a speaker hole (e.g., a piezo speaker).

A sensor module (e.g., the sensor module 176 of FIG. 1) may generate an electrical signal or data value corresponding to an external environment state or an internal operating state of the wearable electronic device 101. In an embodiment, the sensor module may include the first sensor module 211 which is a biometric sensor (e.g., an HRM sensor) disposed on the second surface 210B of the housing 210. The wearable electronic device 101 may further include a sensor module which is not illustrated, for example, at least one of a gesture sensor, a gyro sensor, an air pressure sensor, a magnetic sensor, an acceleration sensor, a grip sensor, a color sensor, an infrared (IR) sensor, a biometric sensor, a temperature sensor, a humidity sensor, and an illuminance sensor.

The key input devices 202, 204a, and 204b may include a wheel key 202 disposed on the first surface 210A of the housing 210 and rotatable in at least one direction, and/or side key buttons 204a and 204b disposed on the lateral surface 210C of the housing 210. The wheel key 202 may have a shape corresponding to the shape of the front plate 201. In an embodiment, the wearable electronic device 101 may not include some or all of the above-mentioned key input devices 202, 204a, and 204b, and the key input devices 202, 204a, and 204b, which are not included therein, may be implemented in a form such as a soft key on the display 220. The connector hole 209 may include another connector hole (not shown) which may receive a connector (for example, a USB connector) for transmitting or receiving power and/or data to or from an external electronic device, and receive a connector for transmitting or receiving an audio signal to or from an external electronic device. The wearable electronic device 101 may further include, for example, a connector cover (not shown) which covers at least a part of the connector hole 209 and blocks the introduction of external foreign substances into the connector hole.

The wearing members 215 and 216 may be detachably bound to at least a partial area of the housing 210 using locking members 215b and 216a. The locking members 215b and 216a may include binding components such as pogo pins, and may be replaced with (protrusion(s) or recess(es)) formed on the wearing members 215 and 216, according to an embodiment. For example, the wearing members 215 and 216 may be coupled to recesses or protrusions formed on the housing 210 in an engaging manner. The wearing members 215 and 216 may include one or more of a fixing member 217, a fixing member fastening hole 215a, a band guide member 218, and a band fixing ring 219.

The fixing member 217 may be configured to fix the housing 210 and the wearing members 215 and 216 to a part of a user's body (e.g., a wrist, an ankle, etc.). The fixing member fastening hole 215a may correspond to the fixing member 217 to fix the housing 210 and the wearing members 215 and 216 to a part of the user's body. The band guide member 218 is configured to limit a range of movement of the fixing member 217 when the fixing member 217 is fastened to the fixing member fastening hole 215a, so that the wearing members 215 and 216 may be in close contact with a part of the user's body to be bound thereto. The band fixing ring 219 may limit a range of movement of the wearing members 215 and 216 in a state in which the fixing member 217 and the fixing member fastening hole 215a are fastened to each other.

FIG. 4 is an exploded perspective view of a wearable electronic device according to various embodiments.

Referring to FIG. 4, the wearable electronic device 101 may include a housing 210 (or a lateral bezel structure) (e.g., the housing 210 of FIGS. 2 and 3), a wheel key 230, a front plate 201 (e.g., the front plate 201 of FIG. 2), a display 220 (e.g., the display module 160 of FIG. 1), a first antenna 250 (e.g., the antenna module 197 of FIG. 1), a second antenna (e.g., an antenna (e.g., the antenna module 197 of FIG. 1) included in an auxiliary circuit board 255), a support member 260 (e.g., a bracket), a battery 245 (e.g., the battery 189 of FIG. 1), a printed circuit board 240, a sealing member 290, a rear plate 292, and wearing members 215 and 216 (e.g., the wearing members 215 and 216 of FIGS. 2 and 3). At least one of the components of the wearable electronic device 101 may be the same as or similar to at least one of the components of the wearable electronic device 101 of FIG. 2 or 3, and a redundant description thereof is omitted below.

In an embodiment, the support member 260 may be disposed inside the wearable electronic device 101 and connected to the housing 210, or may be integrally configured with the housing 210. The support member 260 may be made of, for example, a metal material and/or a non-metal (e.g., polymer) material. The support member 260 may have one surface to which the display 220 is coupled, and the other surface to which the printed circuit board 240 is coupled. A processor (e.g., the processor 120 of FIG. 1), memory (e.g., the memory 130 of FIG. 1), and/or an interface (e.g., the interface 177 of FIG. 1) may be disposed on the printed circuit board 240. The processor may include, for example, one or more of a central processing unit, an application processor, a graphic processing unit (GPU), an application processor, a sensor processor, or a communication processor, each of which may include various processing circuitry as described above with reference to processor 120 of FIG. 1.

The memory may include, for example, volatile memory or nonvolatile memory. The interface may include, for example, a high definition multimedia interface (HDMI), a universal serial bus (USB) interface, an SD card interface, and/or an audio interface. For example, the interface may electrically or physically connect the wearable electronic device 101 to an external wearable electronic device, and include a USB connector, an SD card/MMC connector, or an audio connector.

The battery 245 is a device for supplying power to at least one component of the wearable electronic device 101 and may include, for example, a non-rechargeable primary cell, a rechargeable secondary cell, or a fuel cell. For example, at least a part of the battery 245 may be disposed substantially on the same plane as the printed circuit board 240. The battery 245 may be integrally disposed inside the wearable electronic device 101 or may be disposed to be detachable from the wearable electronic device 101.

The first antenna 250 may be disposed between the display 220 and the support board 260. The first antenna 250 may include, for example, a near field communication (NFC) antenna, a wireless charging antenna, and/or a magnetic secure transmission (MST) antenna. For example, the first antenna 250 may perform short-range communication with an external device or wirelessly transmit or receive power required for charging, and transmit a magnetic-based signal including a short-range communication signal or payment data. In an embodiment, an antenna structure may be configured by a part of the housing 210 and/or the support member 260 or a combination thereof.

The auxiliary circuit board 255 may be disposed between the printed circuit board 240 and the rear plate 292. The auxiliary circuit board 255 may include an antenna, for example, a near field communication (NFC) antenna, a wireless charging antenna, and/or a magnetic secure transmission (MST) antenna. For example, the auxiliary circuit board 255 may perform short-range communication with an external device or wirelessly transmit or receive power required for charging, and transmit a magnetic-based signal including a short-range communication signal or payment data. In an embodiment, an antenna structure may be configured by a part of the housing 210 and/or the rear plate 292 or a combination thereof.

In an embodiment, when the wearable electronic device 101 (e.g., the wearable electronic device 101 of FIGS. 2 and 3) includes a sensor module (e.g., the sensor module 176 of FIG. 1 or the first sensor module 211 of FIG. 3), a separate sensor circuit or sensor element may be disposed in a sensor circuit disposed on the auxiliary circuit board 255. The sensor circuit or sensor element may include, for example, a light-emitting element, a photoelectric conversion element, or an electrode pad.

According to an embodiment, a coil assembly 280 (e.g., a wireless charging coil) may be disposed between the printed circuit board 240 and the rear plate 292. The coil assembly 280 may be electrically connected to the printed circuit board 240 and/or the auxiliary circuit board 255. For example, the coil assembly 280 may be disposed around the auxiliary circuit board 255. The coil assembly 280 may be a charging coil in which a current is induced in response to a magnetic field of a wireless charging device which is externally disposed. In an embodiment, the auxiliary circuit board 255 and the coil assembly 280 may together configure a wireless charging assembly. For example, the auxiliary circuit board 255 and the coil assembly 280 may be integrally configured.

The sealing member (e.g., including a seal) 290 may be positioned between the housing 210 and the rear plate 292. The scaling member 290 may be configured to block moisture and foreign substances from being introduced into a space surrounded by the housing 210 and the rear plate 292 from the outside.

The wearing members (e.g., bands) 215 and 216 may be connected to different areas of the housing 210 and may be arranged in a symmetrical shape.

In the following embodiments, the above-described electronic device 101 of FIGS. 1 to 4 may be referred to, and for configurations which can be easily understood through the above-described embodiments, the same reference numerals in the drawings may be assigned or omitted, and detailed descriptions thereof may not be repeated for brevity and clarity.

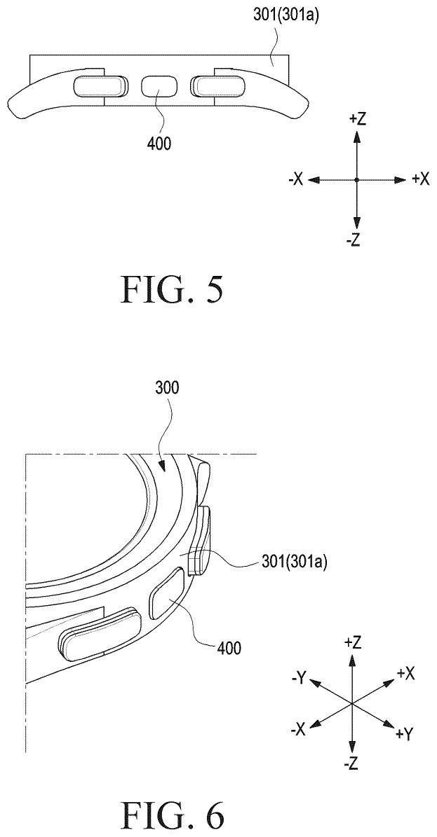

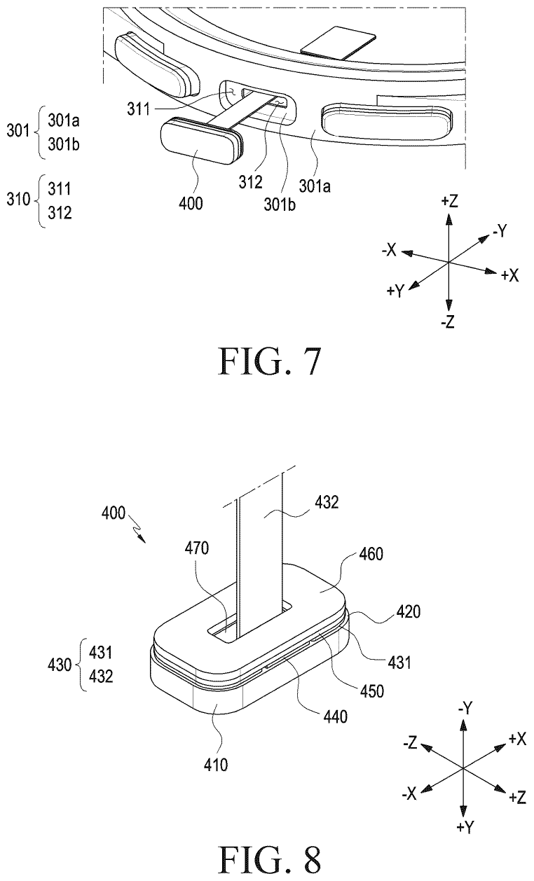

FIG. 5 is a diagram illustrating a side view of an example housing including a fingerprint sensor assembly according to various embodiments. FIG. 6 is a partial perspective view showing a part of a housing including an example fingerprint sensor assembly according to various embodiments. FIG. 7 is a partial exploded perspective view showing an example fingerprint sensor assembly and a housing which are being coupled to each other according to various embodiments.

Referring to FIGS. 5, 6 and 7 (which may be referred to as FIGS. 5 to 7), the wearable electronic device 101 (e.g., the wearable electronic device 101 of FIGS. 2 and 3) may include a housing 300 (e.g., the housing 300 (or the lateral bezel structure) 210 of FIG. 4), and a fingerprint sensor assembly 400 (e.g., the sensor module 176 of FIG. 1) coupled to the housing 300. The configuration of the housing 300 of FIGS. 5 to 7 may be wholly or partly the same as the configuration of the housing 210 of FIGS. 2 to 4. The structures of FIGS. 5 to 7 may be selectively coupled with the structures of FIGS. 2 to 4.

According to an embodiment, the housing 300 may include a lateral bezel structure 301 surrounding a space between a front surface (e.g., the front surface 210A of FIG. 2) and a rear surface (e.g., the rear surface 210B of FIG. 2). The lateral bezel structure 301 may include a first surface 301a, which is an external surface of the electronic device. According to an embodiment, at least a part of the first surface 301a may be configured by a curved surface to correspond to the shape of the housing 300. However, the structure of the first surface 301a is not limited to the above embodiment, and may be variously designed and changed. According to an embodiment, the first surface 301a may include at least one opening 310. For example, the opening 310 may be configured to correspond to the shape of the fingerprint sensor assembly 400.

According to an embodiment, the opening 310 may include a first space 311 which is in contact with the outside of the electronic device and has a first size, and a second space 312 which extends from the first space 311 in an inner direction (−Y direction) of the electronic device and has a second size smaller than the first size.

According to an embodiment, the fingerprint sensor assembly 400 may be coupled to the opening so that at least a part of the fingerprint sensor assembly extends through the opening 310. For example, the fingerprint sensor assembly 400 may include a fingerprint sensor 410 and receive information on a fingerprint from a user. When the surface of the user's finger touches the fingerprint sensor 410, the fingerprint sensor assembly 400 may scan the surface of the user's finger, and generate a fingerprint image using information on the scanned fingerprint, so as to obtain fingerprint information of the user. The fingerprint sensor assembly 400 may include a function of recognizing fingerprint information to perform authentication through the fingerprint recognition.

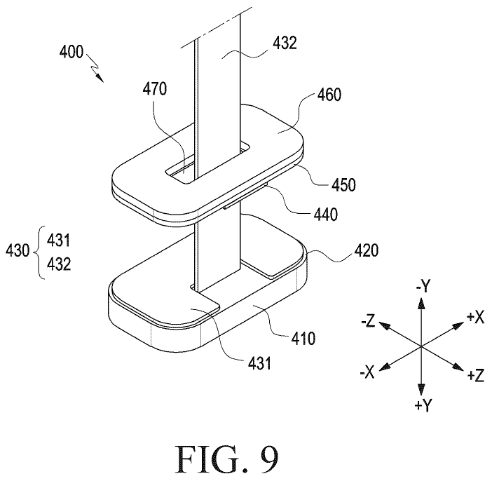

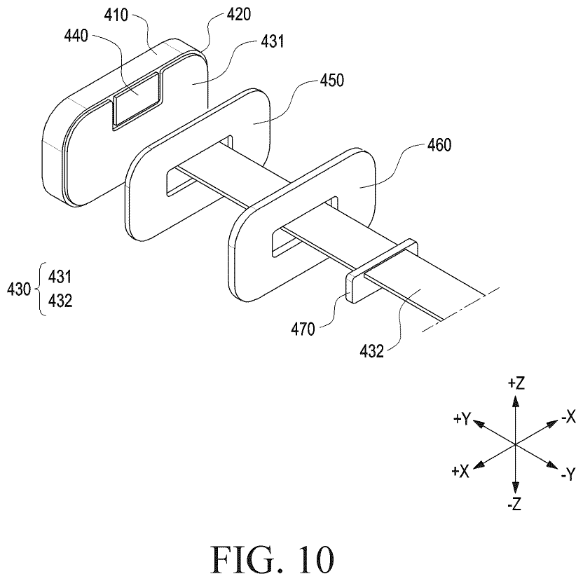

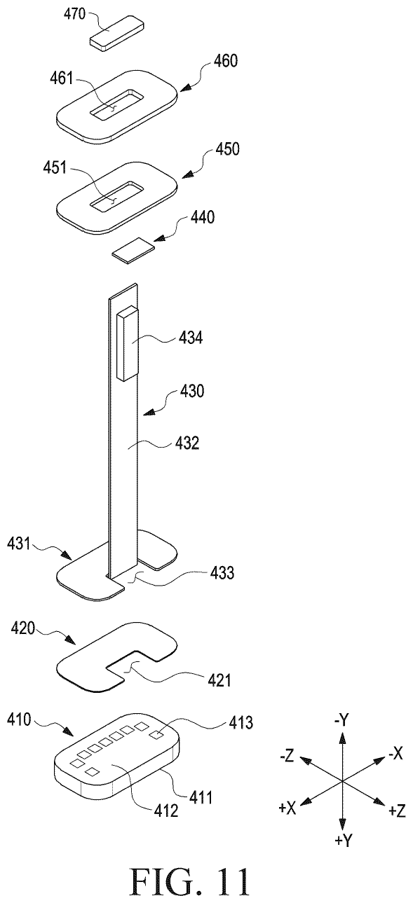

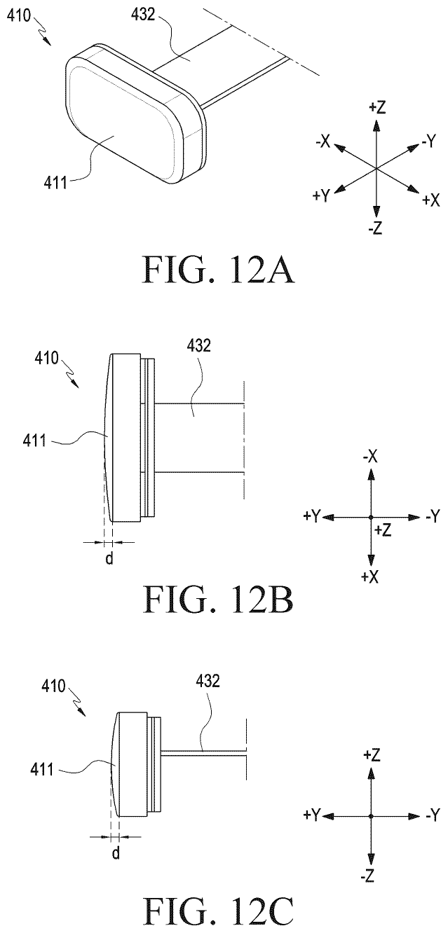

FIG. 8 is a perspective view illustrating an example fingerprint sensor assembly 400 according to various embodiments. FIG. 9 is an exploded perspective view showing the configuration of a fingerprint sensor assembly 400 in a separated state according to various embodiments. FIG. 10 is an exploded perspective view showing the fingerprint sensor assembly 400 of FIG. 9 in a separated state according to various embodiments. FIG. 11 is an exploded perspective view showing the configuration of a fingerprint sensor assembly 400 in a separated state according to various embodiments. FIGS. 12A, 12B and 12C are diagrams and views illustrating an example fingerprint sensor 410 according to various embodiments.

Referring to FIGS. 8, 9, 10, 11, 12A, 12B and 12C (which may be referred to as FIGS. 8 to 12C), the wearable electronic device 101 (e.g., the wearable electronic device 101 of FIGS. 2 and 3) may include a housing 300 (e.g., the housing 300 (or the lateral bezel structure) 210 of FIG. 4), and a fingerprint sensor assembly 400 coupled to the housing 300. The configurations of the housing 300 and the fingerprint sensor assembly 400 of FIGS. 8 to 12C may be wholly or partly the same as the configurations of the housing 210 and the fingerprint sensor assembly 400 of FIG. 5. The structures of FIGS. 8 to 12C may be selectively coupled with the structure of FIG. 5.

According to an embodiment, the fingerprint sensor assembly 400 may include a fingerprint sensor 410, a conductive waterproof film 420 attached to one surface of the fingerprint sensor 410, a first printed circuit board 430 and a reinforcement plate 440 attached to one surface of the conductive waterproof film 420, an adhesive member (e.g., including an adhesive) 450 disposed on the first printed circuit board 430 and the reinforcement plate 440, and a support member (e.g., support) 460 disposed on the adhesive member 450.

According to an embodiment, the fingerprint sensor 410 may include a first surface 411 facing a first direction (e.g., the +Y-axis direction of FIG. 8) which is an outer direction of the electronic device, and a second surface 412 facing a second direction (e.g., the −Y-axis direction of FIG. 8) which is an inner direction of the electronic device. According to an embodiment, the first surface 411 may include a fingerprint measurement area and may be a part where a user's fingerprint touches. According to an embodiment, the first surface 411 may include a curved surface to correspond to the housing 300. For example, when referring to FIGS. 12A, 12B and 12C (which may be referred to as FIGS. 12A to 12C), the first surface 411 may have a constant curvature in the X-axis direction and/or the Z-axis direction. The center part of the first surface 411 may be configured to be more convex than the edge part thereof by a first length d in the first direction (+Y-axis direction). According to an embodiment, the second surface 412 may be in contact with the conductive waterproof film 420. According to an embodiment, the fingerprint sensor 410 may have a rectangular shape. However, the shape of the fingerprint sensor 410 is not limited to the above embodiment.

According to an embodiment, the conductive waterproof film 420 may be disposed on the fingerprint sensor 410. According to an embodiment, the conductive waterproof film 420 may be attached to the second surface 412 of the fingerprint sensor 410. According to an embodiment, the fingerprint sensor 410 and the first printed circuit board 430 may be electrically connected through the conductive waterproof film 420. According to an embodiment, the conductive waterproof film 420 has adhesive properties and thus may bond the fingerprint sensor 410 and the first printed circuit board 430. According to an embodiment, the conductive waterproof film 420 may be an anisotropic conductive film (ACF). However, the conductive waterproof film 420 is not limited to the anisotropic conductive film (ACF) and may include all conductive, waterproof, and adhesive films. According to an embodiment, the waterproof performance of the electronic device can be improved along with an electrical connection between the fingerprint sensor assembly 400 and the first printed circuit board 430 using the conductive waterproof film 420 including waterproof performance. According to an embodiment, the shape of the conductive waterproof film 420 may correspond to the shape of the fingerprint sensor 410. According to an embodiment, the conductive waterproof film may have a first recess 421 which is recessed by a specified length in the inner direction to correspond to the shape of the fingerprint sensor 410.

According to an embodiment, at least a part of the first printed circuit board 430 may be disposed on the conductive waterproof film 420. According to an embodiment, the first printed circuit board 430 may include a first area 431 which is attached to one surface of the conductive waterproof film 420, and a second area 432 which is bent in a vertical direction from the first area 431.

According to an embodiment, the first area 431 of the first printed circuit board 430 may be configured to correspond to the shape of the conductive waterproof film 420. According to an embodiment, the first area 431 may have a second recess 433 which is recessed by a specified length in the inner direction to correspond to the shape of the conductive waterproof film 420. For example, the position and shape of the first recess 421 may substantially correspond to the position and shape of the second recess 433. According to an embodiment, a second output pad portion 435 may be attached to one surface of the first area 431 which is in contact with the conductive waterproof film 420. The second output pad portion 435 may be electrically connected to the conductive waterproof film 420.

According to an embodiment, the second area 432 of the first printed circuit board 430 may extend from the second recess 433 part of the first area 431, and the second area 432 may be bent in the vertical direction at the second recess 433 part of the first area 431. For example, the second area 432 of the first printed circuit board 430 may extend in the inner direction (−Y-axis direction) of the electronic device. The second area 432 may be electrically connected to a second printed circuit board (the printed circuit board 240 of FIG. 4) of the electronic device. For example, one end of the second area 432 may be connected to the first area 431, and the other end of the second area 432 may be connected to the second printed circuit board (the printed circuit board 240 of FIG. 4). For example, the first printed circuit board 430 may be a flexible printed circuit board, and the second printed circuit board (the printed circuit board 240 of FIG. 4) may be a main printed circuit board.

According to an embodiment, the first area 431 of the first printed circuit board 430 may be disposed in a first space 311 of an opening 310, and at least a part of the second area 432 may be disposed in a second space 312 of the opening 310. The second area 432 may extend through the second space 312 of the opening 310 to be connected to the inside of the electronic device.

According to an embodiment, the reinforcement plate 440 may be disposed on the fingerprint sensor 410 in order to reinforce the thicknesses of the second recess 433 part of the first printed circuit board 430 and the first recess 421 part of the conductive waterproof film 420. According to an embodiment, the conductive waterproof film 420 and the first printed circuit board 430 may be attached to a part of the fingerprint sensor 410, and the reinforcement plate 440 may be attached to the remaining part to which the conductive waterproof film 420 and the first printed circuit board 430 are not attached. For example, the fingerprint sensor 410 may include a first part (not shown) to which the first printed circuit board 430 is attached, and a second part (not shown) to which the reinforcement plate 440 is attached. According to an embodiment, the shape of the reinforcement plate 440 may correspond to the shape of the first recess 421 part of the conductive waterproof film 420 and the second recess 433 part of the first printed circuit board 430. According to an embodiment, the thickness of the reinforcement plate 440 may be substantially the same as a thickness obtained by summing the thickness of the conductive waterproof film 420 and the thickness of the first printed circuit board 430. For example, the reinforcement plate 440 may include at least one of polyimide (PI), flame retardant 4 (FR4), and metal. For example, the metal reinforcement plate 440 may be made of at least one of stainless steel and aluminum.

According to an embodiment, the adhesive member 450 may be disposed on the reinforcement plate 440 and the first area 431 of the first printed circuit board 430. For example, the adhesive member 450 may include an adhesive film such as a die attach film, or an adhesive such as an epoxy-based adhesive and adhesive paste. According to an embodiment, the adhesive member 450 may have a waterproof function. For example, the adhesive member 450 may include a waterproof tape. According to an embodiment, the waterproofing performance can be improved using the adhesive member 450 including a waterproofing function. According to an embodiment, the adhesive member 450 may include a first hole 451 configured at a position corresponding to the second area 432 of the first printed circuit board 430. The second area 432 of the first printed circuit board 430 may be coupled to extend through the first hole 451.

According to an embodiment, the support member 460 (stiffener) may be disposed on the adhesive member 450. For example, the support member 460 may include at least one of polyimide (PI), flame retardant 4 (FR4), or metal. For example, the metal support member 460 may be made of at least one of stainless steel and aluminum. According to an embodiment, the support member 460 may include a second hole 461 configured at a position corresponding to the second area 432 of the first printed circuit board 430. The second area 432 of the first printed circuit board 430 may be coupled to extend through the second hole 461.

According to an embodiment, the fingerprint sensor assembly 400 may further include an epoxy 470 disposed to fill the first hole 451 of the adhesive member 450 and the second hole 461 of the support member 460. For example, the waterproof performance of the fingerprint sensor assembly 400 can be improved by filling the first hole 451 of the adhesive member 450 and the second hole 461 of the support member 460 with the epoxy 470 and oven-hardening the same.

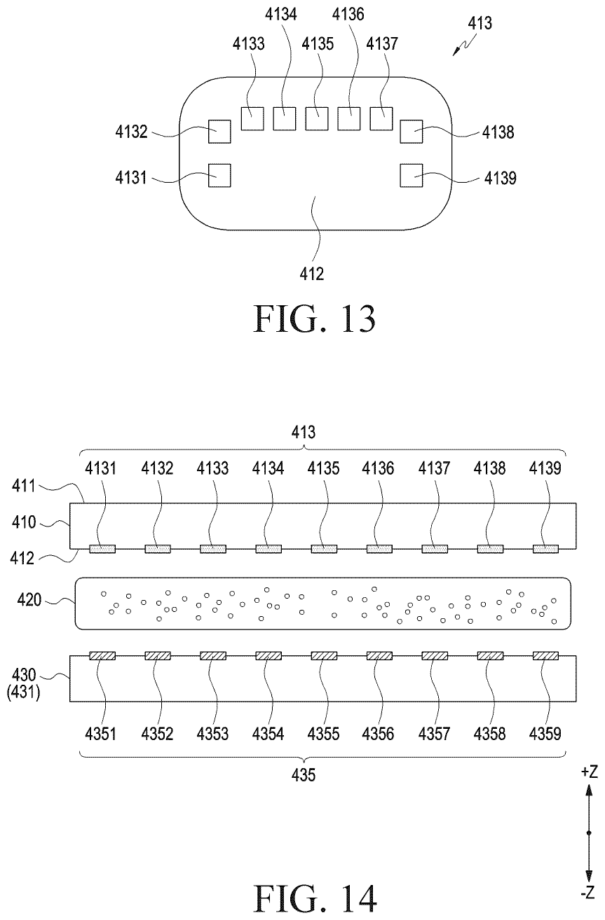

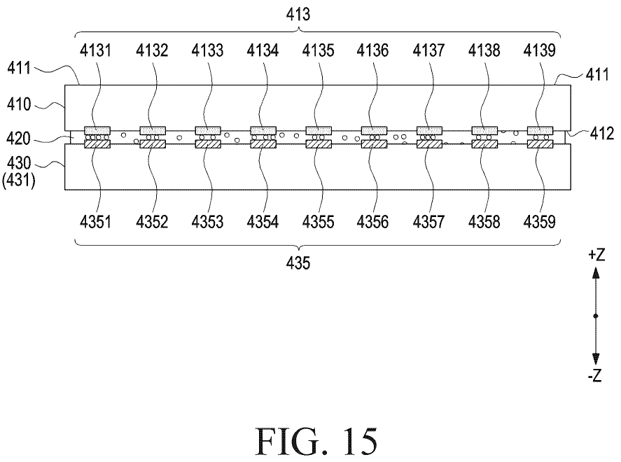

FIG. 13 is a diagram illustrating a second surface 412 of a fingerprint sensor 410 according to various embodiments. FIGS. 14 and 15 are diagrams illustrating an example electrical connection process of a fingerprint sensor 410, a conductive waterproof film 420, and a first printed circuit board 430 according to an various embodiments.

Referring to FIGS. 13, 14 and 15 (which may be referred to as FIGS. 13 to 15), the wearable electronic device 101 (e.g., the wearable electronic device 101 of FIGS. 2 and 3) may include a housing 300 (e.g., the housing 300 (or the lateral bezel structure) 210 of FIG. 4), and a fingerprint sensor assembly 400 coupled to the housing 300. The configurations of the housing 300 and the fingerprint sensor assembly 400 of FIGS. 13 to 15 may be wholly or partly the same as the configurations of the housing 210 and the fingerprint sensor assembly 400 of FIGS. 5 to 12C. The structures of FIGS. 13 to 15 may be selectively coupled with the structures of FIGS. 5 to 12C.

According to an embodiment, the second surface 412 of the fingerprint sensor 410 may include a first output pad portion 413 configured to be electrically connected to the conductive waterproof film 420. The first output pad portion 413 may be configured by a plurality of pins. For example, the plurality of pins may include 9 pins. For example, a first pin 4131 may be VCC, a second pin 4132 may be INT, a third pin 4133 may be MISO, a fourth pin 4134 may be MOSI, a fifth pin 4135 may be CLK, a sixth pin 4136 may be CS, a seventh pin 4137 may be GND, an eighth pin 4138 may be RST, and a ninth pin 4139 may be OTP. However, the number and configuration of the plurality of pins are not limited to the above embodiment, and may be variously designed and changed depending on the size and type of the fingerprint sensor 410.

According to an embodiment, a first area 431 of the first printed circuit board 430 may include a second output pad portion 435 configured to be electrically connected to the conductive waterproof film 420. The second output pad portion 435 may be configured by a plurality of pins. For example, the plurality of pins may include 9 pins. For example, a first pin 4351 may be VCC, a second pin 4352 may be INT, a third pin 4353 may be MISO, a fourth pin 4354 may be MOSI, a fifth pin 4355 may be CLK, a sixth pin 4356 may be CS, a seventh pin 4357 may be GND, an eighth pin 4358 may be RST, and a ninth pin 4359 may be OTP. However, the number and configuration of the plurality of pins are not limited to the above embodiment, and may be variously designed and changed depending on the size and type of the fingerprint sensor 410.

According to an embodiment, the conductive waterproof film 420 may be an anisotropic conductive film (ACF). The anisotropic conductive film (ACF) may be an anisotropic conductive film made by mixing fine conductive particles with a thermosetting adhesive resin into a film state and conduct electricity through the film state resin in only one direction. The anisotropic conductive film (ACF) may be a thin film made by mixing an adhesive which does not conduct electricity and fine conductive particles configured to conduct electricity. If the anisotropic conductive film (ACF) is placed between the fingerprint sensor 410 and the first printed circuit board 430 which are to be connected and is then pressed, the connected components can conduct electricity through each other. For example, the fine conductive particles may be nickel (Ni), carbon, or lead balls (solder balls).

According to an embodiment, the fingerprint sensor 410 and the first printed circuit board 430 may be electrically connected through the conductive waterproof film 420. For example, when referring to FIGS. 13 to 15, the first output pad portion 413 disposed on the fingerprint sensor 410 and the second output pad portion 435 disposed on the first printed circuit board 430 may be electrically connected through the conductive waterproof film 420. Even when the first output pad portion 413 and the second output pad portion 435 are not in direct contact with each other, the first printed circuit board 430 and the fingerprint sensor 410 may be electrically connected to each other through physical and electrical coupling through the anisotropic conductive film (ACF). According to an embodiment, by electrically connecting the fingerprint sensor 410 and the first printed circuit board 430 through the anisotropic conductive film (ACF), even without adding a separate waterproof structure, the waterproof performance of the fingerprint sensor assembly 400 can be improved, and the fingerprint sensor assembly 400 may be configured to be coupled to the outer part of the housing 300, so that the size of the fingerprint sensor assembly may be relatively large.

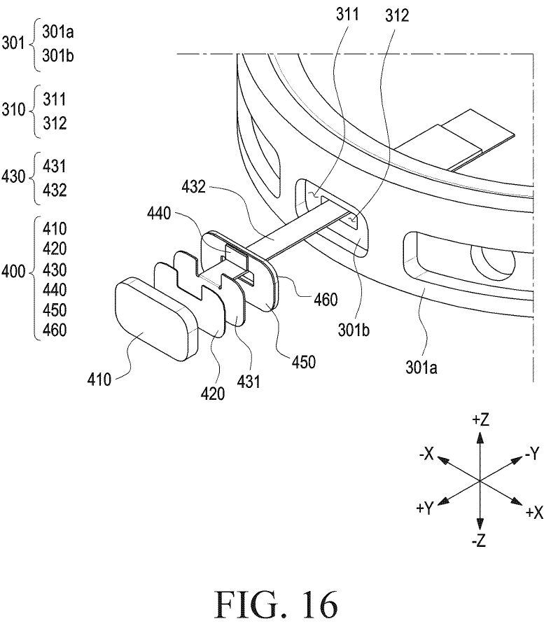

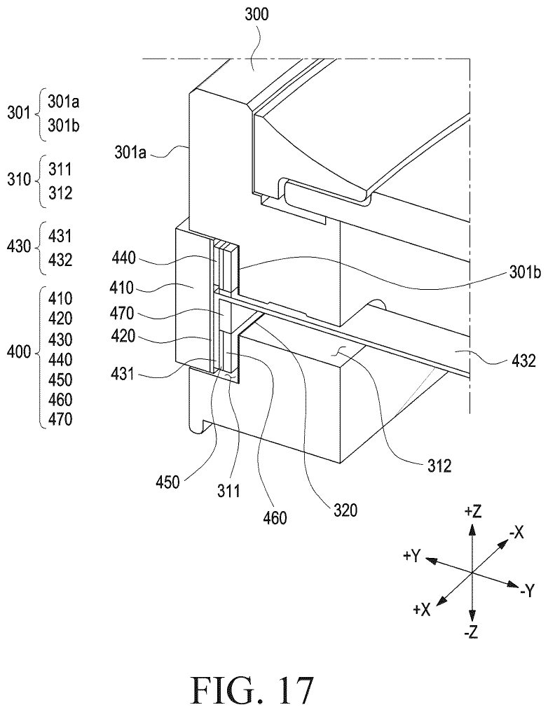

FIG. 16 is a partial exploded perspective view illustrating an example fingerprint sensor assembly 400 which is being coupled to a housing 300 according various embodiments. FIG. 17 is a partial cross-sectional perspective view of a housing 300 coupled with a fingerprint sensor assembly 400 according to various embodiments.

Referring to FIGS. 16 and 17, the wearable electronic device 101 (e.g., the wearable electronic device 101 of FIGS. 2 and 3) may include a housing 300 (e.g., the housing 300 (or the lateral bezel structure) 210 of FIG. 4), and a fingerprint sensor assembly 400 coupled to the housing 300. The configurations of the housing 300 and the fingerprint sensor assembly 400 of FIGS. 16 and 17 may be wholly or partly the same as the configurations of the housing 210 and the fingerprint sensor assembly 400 of FIG. 5. The structures of FIGS. 16 and 17 may be selectively coupled with the structure of FIG. 5.

According to an embodiment, an opening 310 may include a first space 311 which is in contact with the outside of the electronic device and has a first size, and a second space 312 which extends from the first space 311 in an inner direction (−Y direction) of the electronic device and has a second size smaller than the first size. According to an embodiment, a lateral bezel structure 301 of the housing may further include a first surface 301a which is an external surface of the electronic device, and a second surface 301b which is a reference surface that a user cannot identify from the outside of the electronic device but that separates the first space 311 and the second space 312, and is configured according to the size difference between the first space 311 and the second space 312. For example, the second surface 301b may be an attachment surface to which the fingerprint sensor assembly 400 is attached.

According to an embodiment, the fingerprint sensor assembly 400 and the housing 300 may be configured to be coupled by a waterproof adhesive member 320 disposed between the fingerprint sensor assembly 400 and the housing 300. As the fingerprint sensor assembly 400 and the housing 300 are coupled by the waterproof adhesive member 320, the waterproof performance can be maintained and/or improved even when the fingerprint sensor assembly 400 is placed in the outer part of the electronic device.

According to an embodiment, the fingerprint sensor assembly 400 may be coupled to the opening so that at least a part of the fingerprint sensor assembly extends through the opening 310. According to an embodiment, the fingerprint sensor assembly 400 may be positioned within the first space 311 of the opening 310. For example, the fingerprint sensor assembly 400 may be attached to the second surface 301b. The fingerprint sensor assembly 400 is positioned in the first space 311 close to an outer direction (+Y-axis direction) of the electronic device, so that the size of a fingerprint sensor area is relatively large, making it convenient to use.

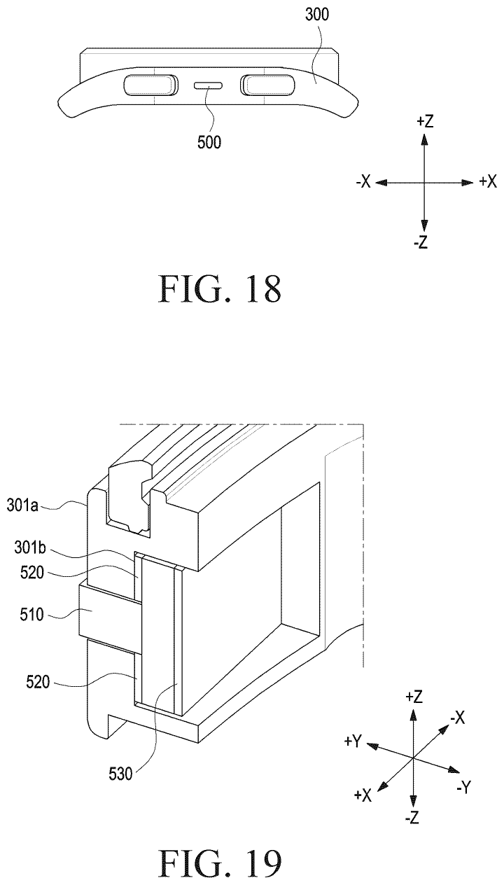

FIG. 18 is a diagram illustrating a side view of a housing 300 including a fingerprint sensor assembly 500 according to various embodiments. FIG. 19 is a partial cross-sectional perspective view of a housing 300 coupled with a fingerprint sensor assembly 500 according to various embodiments.

Referring to FIGS. 18 and 19, the wearable electronic device 101 (e.g., the wearable electronic device 101 of FIGS. 2 and 3) may include a housing 300 (e.g., the housing 300 (or the lateral bezel structure) 210 of FIG. 4), and a fingerprint sensor assembly 500 coupled to the housing 300. The configurations of the housing 300 and the fingerprint sensor assembly 500 of FIGS. 18 and 19 may be wholly or partly the same as the configurations of the housing 210 and the fingerprint sensor assembly 400 of FIGS. 5 to 17. The structures of FIGS. 18 and 19 may be selectively coupled with the structures of FIGS. 5 to 17.

According to an embodiment, the housing 300 may include a lateral bezel structure 301 surrounding a space between a front surface (e.g., the front surface 210A of FIG. 2) and a rear surface (e.g., the rear surface 210B of FIG. 2). The lateral bezel structure 301 may include a first surface 301a which is an external surface of the electronic device. According to an embodiment, the first surface 301a may include at least one opening 310. For example, the opening 310 may be configured to correspond to the shape of the fingerprint sensor assembly 400.

According to an embodiment, the opening 310 may include a first space 311 which is in contact with the outside of the electronic device and has a first size, and a second space 312 which extends from the first space 311 in an inner direction (−Y direction) of the electronic device and has a second size larger than the first size.

According to an embodiment, the fingerprint sensor assembly 500 may be coupled to the opening so that at least a part of the fingerprint sensor assembly extends through the opening 310. According to an embodiment, the fingerprint sensor assembly 500 may include a fingerprint sensor 510, a support member (not shown) attached to one surface of the fingerprint sensor 510, a waterproof member 520 disposed between the support member (not shown) and a second surface 301b, and a first printed circuit board 530 attached to one surface of the support member (not shown).

According to an embodiment, the waterproof member 520 may include at least one of, for example, a waterproof tape and a bonding member.

According to an embodiment, when the fingerprint sensor assembly and the electronic device are coupled to each other, a separate support member is required to be disposed inside the electronic device, assembly may be difficult, and costs may increase. When the fingerprint sensor assembly is disposed in the inner part of the electronic device, a fingerprint measurement area of the fingerprint sensor is reduced due to a waterproof member, which may make it difficult to secure performance.

According to an embodiment of the disclosure, the fingerprint sensor assembly is disposed in the outer part of the wearable electronic device to expand the fingerprint measurement area, and the fingerprint sensor assembly can maintain and improve the waterproof performance by using a conductive waterproof member.

According to an embodiment, by electrically connecting a fingerprint sensor 410 and a first printed circuit board 430 through an anisotropic conductive film (ACF), even without adding a separate waterproof structure, the waterproof performance of the fingerprint sensor assembly 400 can be improved, and the fingerprint sensor assembly 400 may be configured to be coupled to the outer part of the housing 300, so that the size of the fingerprint sensor assembly may be relatively large.

According to an embodiment of the disclosure, the fingerprint sensor assembly 400 may include an adhesive member 450 having a waterproof function and an epoxy 470, and the fingerprint sensor assembly 400 and the housing 300 are configured to be coupled by a waterproof adhesive member 320 disposed between the fingerprint sensor assembly 400 and the housing 300, so that the waterproof performance can be maintained and/or improved even when the fingerprint sensor assembly 400 is placed in the outer part of the electronic device.

An electronic device according to an example embodiment of the disclosure may include: a housing including a first surface having an opening formed therethrough, and a fingerprint sensor assembly coupled to the opening so that at least a part of the fingerprint sensor assembly extends through the opening, wherein the fingerprint sensor assembly includes: a fingerprint sensor, a conductive waterproof film attached to one surface of the fingerprint sensor, and a first printed circuit board at least partially attached to one surface of the conductive waterproof film, wherein the opening includes a first space in contact with the outside of the electronic device and having a first size, and a second space extending from the first space in an inner direction of the electronic device and having a second size smaller than the first size, the fingerprint sensor assembly being positioned within the first space.

According to an example embodiment, the conductive waterproof film may include an anisotropic conductive film.

According to an example embodiment, the first printed circuit board may include a first area attached to the conductive waterproof film, and a second area bent in a substantially vertical direction from the first area, and the first area may be disposed within the first space, and at least a part of the second area may be disposed within the second space.

According to an example embodiment, the first area of the first printed circuit board may include a recess configured to be connected to the second area, and the fingerprint sensor assembly may further include a reinforcement plate corresponding to a shape of the recess, disposed on the fingerprint sensor, and having a thickness substantially the same as a thickness of the first printed circuit board.

According to an example embodiment, the fingerprint sensor assembly may further include an adhesive member comprising an adhesive disposed on the first area of the first printed circuit board and the reinforcement plate and including a first hole configured to allow the second area of the first printed circuit board to extend therethrough.

According to an example embodiment, the fingerprint sensor assembly may further include a support disposed on the adhesive member and including a second hole configured to allow the second area of the first printed circuit board to extend therethrough.

According to an example embodiment, the fingerprint sensor assembly may further include an epoxy disposed to fill the first hole of the adhesive member and the second hole of the support.

According to an example embodiment, the housing may further include a second surface positioned between the first space and the second space, and the second surface may be configured so that the fingerprint sensor assembly is attached thereto.

According to an example embodiment, the fingerprint sensor may include a first surface facing a first direction (e.g., the +Y-axis direction of FIG. 8) which is an outer direction of the electronic device, and including a fingerprint measurement area, and a second surface facing a second direction (e.g., the −Y-axis direction of FIG. 8) opposite to the first direction, and in contact with a conductive waterproof member comprising a conductive waterproof film.

According to an example embodiment, based on at least a part of the housing being configured by a curved surface, the first surface may include a curved surface corresponding to the curved surface of the housing.

According to an example embodiment, a first output pad portion including at least one output pad disposed on the fingerprint sensor and a second output pad portion including at least one output pad disposed on the first printed circuit board may be configured to be electrically connected through the conductive waterproof film.

According to an example embodiment, the conductive waterproof film may include a first part to which the first printed circuit board is attached, and a second part to which the reinforcement plate is attached.

According to an example embodiment, the fingerprint sensor assembly and the housing may be coupled by a waterproof adhesive member comprising a waterproof adhesive material disposed between the fingerprint sensor assembly and the housing.

According to an example embodiment, the second area of the first printed circuit board may be electrically connected to a second printed circuit board disposed inside the housing.

An electronic device according to an example embodiment of the disclosure may include: a housing including a first surface having an opening formed therethrough, and a fingerprint sensor assembly coupled to the opening so that at least a part of the fingerprint sensor assembly extends through the opening, wherein the fingerprint sensor assembly includes: a fingerprint sensor, a conductive waterproof film attached to one surface of the fingerprint sensor, a first printed circuit board including a first area at least partially attached to the conductive waterproof film and a second area bent in a vertical direction from the first area, a reinforcement plate at least partially attached to the conductive waterproof film, an adhesive member comprising an adhesive material disposed on the first area of the first printed circuit board and the reinforcement plate and including a first hole positioned to correspond to the second area of the first printed circuit board, a support disposed on the adhesive member and including a second hole positioned to correspond to the second area of the first printed circuit board, and an epoxy disposed to fill the first hole of the adhesive member and the second hole of the support, the opening includes a first space in contact with the outside of the electronic device and having a first size, and a second space extending from the first space in an inner direction of the electronic device and having a second size smaller than the first size, wherein the fingerprint sensor assembly is positioned within the first space.

According to an example embodiment, the conductive waterproof film may include an anisotropic conductive film.

According to an example embodiment, the first area of the first printed circuit board may be disposed in the first space, and the second area may be disposed in the second space.

According to an example embodiment, the housing may further include a second surface positioned between the first space and the second space, wherein the second surface may be configured so that the fingerprint sensor assembly is attached thereto.

According to an example embodiment, the fingerprint sensor assembly and the housing may be coupled by a waterproof adhesive member comprising a waterproof adhesive material disposed between the fingerprint sensor assembly and the housing.

According to an example embodiment, a first output pad portion disposed on the fingerprint sensor and a second output pad portion disposed on the first printed circuit board may be configured to be electrically connected through the conductive waterproof film.

While the disclosure has been illustrated and described with reference to various example embodiments, it will be understood that the various example embodiments are intended to be illustrative, not limiting. It will be further understood by those skilled in the art the various changes in form and detail may be made without departing from the true spirit and full scope of the disclosure, including the appended claims and their equivalents. It will also be understood that any of the embodiment(s) described herein may be use in conjunction with any other embodiment(s) described herein.

What is claimed is:

1. An electronic device comprising:
a housing including an opening formed through a first surface of the housing; and
a fingerprint sensor assembly coupled so that at least a part of the fingerprint sensor assembly is disposed to pass through the opening,
wherein the fingerprint sensor assembly comprises:
a fingerprint sensor;
a conductive waterproof film attached to one surface of the fingerprint sensor; and
a first printed circuit board at least partially attached to one surface of the conductive waterproof film,
wherein the opening includes a first space exposed to an outside of the electronic device and having a first size, and a second space extending from the first space in an inner direction of the electronic device and having a second size smaller than the first size, and
at least a part of the fingerprint sensor assembly is positioned in the first space.

2. The electronic device of claim 1, wherein the conductive waterproof film comprises an anisotropic conductive film.

3. The electronic device of claim 1, wherein the first printed circuit board includes a first area attached to the conductive waterproof film, and a second area bent in a substantially vertical direction from the first area, and
wherein the first area is disposed in the first space, and the second area is at least partially disposed in the second space.

4. The electronic device of claim 3, wherein the first area of the first printed circuit board comprises a recess configured to be connected to the second area, and
the fingerprint sensor assembly further comprises a reinforcement plate corresponding to a shape of the recess, disposed on the fingerprint sensor, and having a thickness substantially the same as a thickness of the first printed circuit board.

5. The electronic device of claim 4, wherein the fingerprint sensor assembly further comprises an adhesive member comprising an adhesive material disposed on the first area of the first printed circuit board and the reinforcement plate and including a first hole through which the second area of the first printed circuit board passes.

6. The electronic device of claim 5, wherein the fingerprint sensor assembly further comprises a support disposed on the adhesive member and including a second hole through which the second area of the first printed circuit board passes.

7. The electronic device of claim 6, wherein the fingerprint sensor assembly further comprises an epoxy disposed to fill the first hole of the adhesive member and the second hole of the support.

8. The electronic device of claim 1, wherein the housing further includes a second surface positioned between the first space and the second space, and the second surface is configured so that the fingerprint sensor assembly is attached thereto.

9. The electronic device of claim 1, wherein the fingerprint sensor includes a first surface facing a first direction, the first direction being an outer direction of the electronic device and including a fingerprint measurement area, and a second surface facing a second direction opposite to the first direction, and in contact with the conductive waterproof member.

10. The electronic device of claim 8, wherein at least a part of the housing has a curved surface, and the first surface includes a curved surface corresponding to the curved surface of the housing.

11. The electronic device of claim 1, wherein a first output pad portion disposed on the fingerprint sensor and a second output pad portion disposed on the first printed circuit board are configured to be electrically connected through the conductive waterproof film.

12. The electronic device of claim 4, wherein the conductive waterproof film includes a first part to which the first printed circuit board is attached, and a second part to which the reinforcement plate is attached.

13. The electronic device of claim 1, wherein the fingerprint sensor assembly and the housing are coupled by a waterproof adhesive member comprising a waterproof adhesive material disposed between the fingerprint sensor assembly and the housing.

14. The electronic device of claim 3, wherein the second area of the first printed circuit board is electrically connected to a second printed circuit board disposed in the housing.

15. An electronic device comprising:
a housing including an opening formed through a first surface of the housing; and
a fingerprint sensor assembly coupled so that at least a part of the fingerprint sensor assembly is disposed to pass through the opening,
wherein the fingerprint sensor assembly comprises:
a fingerprint sensor;
a conductive waterproof film attached to one surface of the fingerprint sensor;
a first printed circuit board including a first area at least partially attached to the conductive waterproof film, and a second area bent in a vertical direction from the first area;
a reinforcement plate at least partially attached to the conductive waterproof film;
an adhesive member comprising an adhesive material disposed on the first area of the first printed circuit board and the reinforcement plate and including a first hole positioned to correspond to the second area of the first printed circuit board;
a support disposed on the adhesive member and including a second hole positioned to correspond to the second area of the first printed circuit board; and
an epoxy disposed to fill the first hole of the adhesive member and the second hole of the support,
wherein the opening includes a first space exposed to an outside of the electronic device and having a first size, and a second space extending from the first space in an inner direction of the electronic device and having a second size smaller than the first size, and
the fingerprint sensor assembly is positioned in the first space.

16. The electronic device of claim 15, wherein the conductive waterproof film comprises an anisotropic conductive film.

17. The electronic device of claim 15, wherein the first area of the first printed circuit board is disposed in the first space, and the second area is disposed in the second space.

18. The electronic device of claim 15, wherein the housing further includes a second surface positioned between the first space and the second space, and the second surface is configured so that the fingerprint sensor assembly is attached thereto.

19. The electronic device of claim 15, wherein the fingerprint sensor assembly and the housing are coupled by a waterproof adhesive member comprising a waterproof adhesive material disposed between the fingerprint sensor assembly and the housing.

20. The electronic device of claim 15, wherein a first output pad portion disposed on the fingerprint sensor and a second output pad portion disposed on the first printed circuit board are configured to be electrically connected through the conductive waterproof film.
